(19) United States
(12) Patent Application Publication
(10) Pub. No.: US 2008/0128854 A1
(43) Pub. Date: Jun. 5, 2008

(54) Embedded array capacitor with top and bottom exterior surface metallization

(76) Inventors: Anne E. Augustine, Chandler, AZ (US); Leigh E. Wojewoda, Tempe, AZ (US); Michael J. Hill, Gilbert, AZ (US)

Correspondence Address: INTEL CORPORATION;c/o INTELLEVATE, LLC, P.O. BOX 52050, MINNEAPOLIS, MN, 55402, US

(21) Appl. No.: 11/634,026

(22) Filed: Dec. 4, 2006

(51) Int. Cl. H01L 29/00

(52) U.S. Cl. 257/532

(57) ABSTRACT

In some embodiments, an embedded array capacitor with top and bottom exterior surface metallization is presented. In this regard, an integrated circuit package is introduced having a plurality of micro-vias, a plurality of dielectric layers, and an array capacitor with metallization substantially covering an exterior surface coupled with the micro-vias and embedded in the dielectric layers. Other embodiments are also disclosed and claimed.

### FIELD OF THE INVENTION

Embodiments of the present invention generally relate to the field of integrated circuit packages, and, more particularly to an embedded array capacitor with top and bottom exterior surface metallization.

### BACKGROUND OF THE INVENTION

Array capacitors are being embedded in the substrates of high frequency integrated circuit packages to manage power delivery to the die(s). Core layers, which are generally removed to make room for array capacitors, tend to be thicker and less resistive than build up layers. Therefore, the removal of core layers tends to result in a high package resistance.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of an array capacitor with top and bottom exterior surface metallization, in accordance with one example embodiment of the invention;

FIG. 2 is a graphical illustration of an overhead view of an array capacitor with top exterior surface metallization, in accordance with one example embodiment of the invention;

FIG. 3 is a graphical illustration of a cross-sectional view of an IC package including an embedded array capacitor with top and bottom exterior surface metallization, in accordance with one example embodiment of the invention; and

FIG. 4 is a block diagram of an example electronic appliance suitable for implementing an IC package including an embedded array capacitor with top and bottom exterior surface metallization, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of an array capacitor with top and bottom exterior surface metallization, in accordance with one example embodiment of the invention. In accordance with the illustrated example embodiment, array capacitor 100 includes one or more of capacitor plates 102, top surface metallization 104, vertical vias 106, and bottom surface metallization 108.

Capacitor plates 102 represent a plurality of conductive plates separated by insulators to store a charge. In one embodiment, capacitor plates 102 comprise about 500 layers.

Top surface metallization 104 represents metal such copper that has been deposited or formed on an exterior surface of array capacitor 100 and couples with one or more vertical vias 106. While the thickness of top surface metallization can vary, in one embodiment top surface metallization 104 is about 75 micrometers thick.

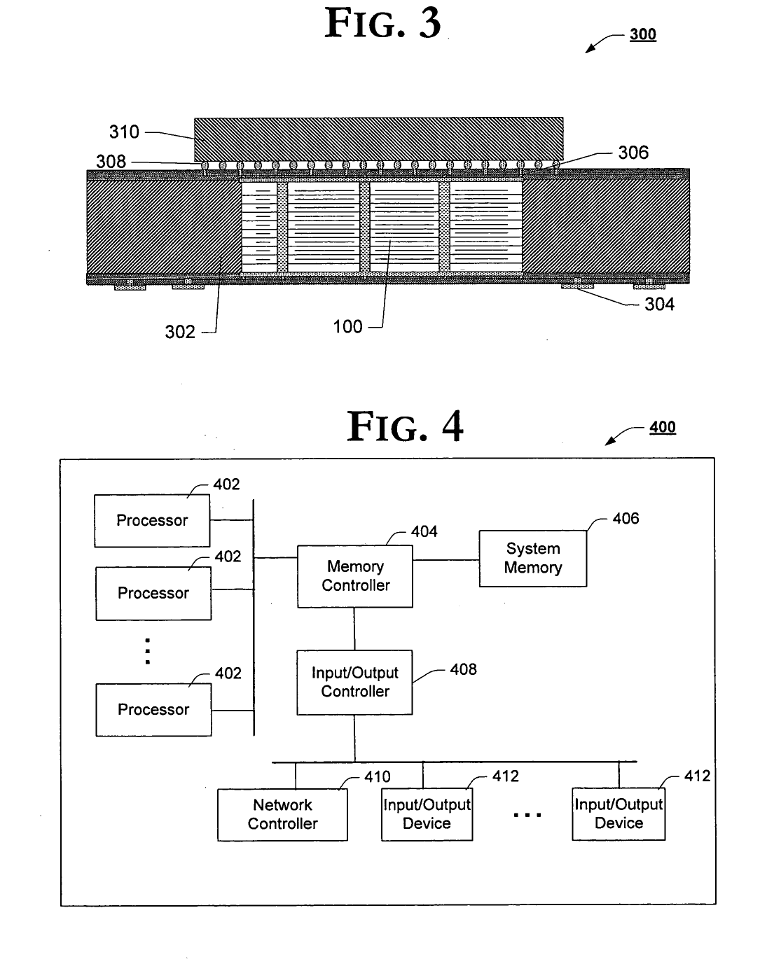

Vertical vias 106 represent metalized terminals that can carry current as part of a power deliver solution for an integrated circuit package, for example, as shown in FIG. 3. Vertical vias 106 may or may not be connected to capacitor plates 102.

Bottom surface metallization 108 represents metal such as copper that has been deposited or formed on an exterior surface of array capacitor 100 and couples with one or more vertical vias 106. One skilled in the art would appreciate that the addition of top surface metallization 104 and bottom surface metallization 108 can lower the resistance of an integrated circuit package which had core layers removed to accommodate an array capacitor.

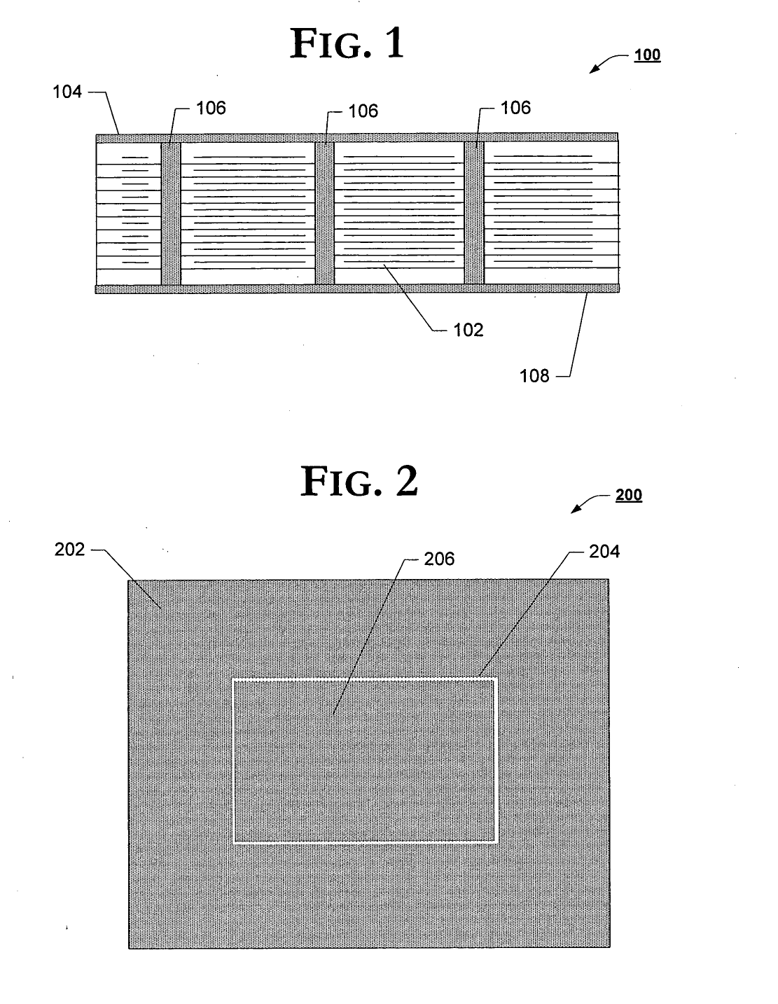

FIG. 2 is a graphical illustration of an overhead view of an array capacitor with top exterior surface metallization, in accordance with one example embodiment of the invention. As shown, array capacitor 200 includes one or more of first metallization region 202, insulating barrier 204 and second metallization region 206. While shown as being square in shape, array capacitor 200 may encompass any shape without deviating from the scope of the present invention. Also, while shown as including two metallization regions (202 and 206) array capacitor may include any number of electrically isolated metallization regions for power and ground. In one embodiment, array capacitor 200 is about 1 square centimeter in size. In one embodiment, insulating barrier 204 is an epoxy that electrically isolates region 202 from region 206.

FIG. 3 is a graphical illustration of a cross-sectional view of an IC package including an embedded array capacitor with top and bottom exterior surface metallization, in accordance with one example embodiment of the invention. As shown, IC package 300 includes one or more of array capacitor 100, dielectric layers 302, package connections 304, micro-vias 306, die bumps 308 and die 310. While shown with a single array capacitor 100, IC package 300 may include more than one array capacitor.

Dielectric layers 302 represent organic dielectric material, such as epoxy based dielectric, that has been added to a substrate as part of a build-up process. Metal traces, not shown, may be included in dielectric layers 302 to route signals to and from die 310. To accommodate array capacitor 100, a portion of dielectric layers 302 may be removed, by etching or drilling for example, to expose micro-vias, or conductive elements coupled with package connections 304.

Package connections 304 provide an interface between IC package 300 and other components, for example through a socket. In one embodiment, signals are routed through package connections 304 to traces in dielectric layers 302 while power and ground are routed through package connections 304 to metallization regions on the bottom surface of array capacitor 100.

Micro-vias 306 may be formed on top of metallization regions on the top surface of array capacitor 100 as part of a manufacturing process to route the vertical vias in array capacitor 100 to the top of the package substrate.

Die bumps 308 may provide the mechanical and electrical connection between micro-vias 306 and die 310.

Die 310 may represent any type of integrated circuit device or devices that may benefit from the use of an array capacitor with top and bottom exterior surface metallization, for example a multi-core processor.

FIG. 4 is a block diagram of an example electronic appliance suitable for implementing an IC package including an embedded array capacitor with top and bottom exterior surface metallization, in accordance with one example embodiment of the invention. Electronic appliance 400 is intended to represent any of a wide variety of traditional and non-traditional electronic appliances, laptops, desktops, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 400 may include one or more of processor(s) 402, memory controller 404, system memory 406, input/output controller 408, network controller 410, and input/output device(s) 412 coupled as shown in FIG. 4. Processor(s) 402, or other integrated circuit components of electronic appliance 400, may be housed in a package including a substrate with an embedded array capacitor with top and bottom exterior surface metallization described previously as an embodiment of the present invention.

Processor(s) 402 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 402 are Intel® processors. Processor(s) 402 may have an instruction set containing a plurality of machine level instructions that may be invoked, for example by an application or operating system.

Memory controller 404 may represent any type of chipset or control logic that interfaces system memory 406 with the other components of electronic appliance 400. In one embodiment, the connection between processor(s) 402 and memory controller 404 may be referred to as a front-side bus. In another embodiment, memory controller 404 may be referred to as a north bridge.

System memory 406 may represent any type of memory device(s) used to store data and instructions that may have been or will be used by processor(s) 402. Typically, though the invention is not limited in this respect, system memory 406 will consist of dynamic random access memory (DRAM). In one embodiment, system memory 406 may consist of Rambus DRAM (RDRAM). In another embodiment, system memory 406 may consist of double data rate synchronous DRAM (DDRSDRAM).

Input/output (I/O) controller 408 may represent any type of chipset or control logic that interfaces I/O device(s) 412 with the other components of electronic appliance 400. In one embodiment, I/O controller 408 may be referred to as a south bridge. In another embodiment, I/O controller 408 may comply with the Peripheral Component Interconnect (PCI) Express™ Base Specification, Revision 1.0a, PCI Special Interest Group, released Apr. 15, 2003.

Network controller 410 may represent any type of device that allows electronic appliance 400 to communicate with other electronic appliances or devices. In one embodiment, network controller 410 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 410 may be an Ethernet network interface card.

Input/output (I/O) device(s) 412 may represent any type of device, peripheral or component that provides input to or processes output from electronic appliance 400.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An integrated circuit chip package substrate comprising:
a plurality of micro-vias;
a plurality of dielectric layers; and
an array capacitor with metallization substantially covering an exterior surface coupled with the micro-vias and embedded in the dielectric layers.

2. The integrated circuit chip package substrate of claim 1, wherein the array capacitor comprises a substantially square shape with substantially metalized top and bottom exterior surfaces.

3. The integrated circuit chip package substrate of claim 2, wherein the array capacitor is about 1 square centimeter in size.

4. The integrated circuit chip package substrate of claim 2, wherein the array capacitor comprises about 500 layers.

5. The integrated circuit chip package substrate of claim 2, wherein the substantially metalized exterior surfaces comprise electrically isolated power and ground regions.

6. The integrated circuit chip package substrate of claim 5, wherein the electrically isolated power and ground regions are separated by an epoxy.

7. The integrated circuit chip package substrate of claim 1, further comprising a second array capacitor.

8. An apparatus comprising:
an integrated circuit die; and
a substrate, including an embedded array capacitor with a substantially metalized exterior surface.

9. The apparatus of claim 8, wherein the array capacitor comprises a substantially square array capacitor with metallization of a top and a bottom exterior surfaces.

10. The apparatus of claim 9, wherein the metalized surfaces comprise a thickness of about 75 micrometers.

11. The apparatus of claim 9, wherein the metalized surfaces comprise electrically isolated power and ground regions.

12. An electronic appliance comprising:
a network controller;
a system memory; and
a processor, wherein the processor includes a substrate, including a substantially square embedded array capacitor including substantially metalized top and bottom exterior surfaces.

13. The electronic appliance of claim 12, wherein the metalized surfaces comprise a thickness of about 75 micrometers.

14. The electronic appliance of claim 12, wherein the array capacitor is about 1 square centimeter in size.

15. The electronic appliance of claim 12, wherein the substantially metalized surfaces comprise electrically isolated regions for power and ground.

16. A method comprising:
exposing a plurality of micro-vias in a substrate; and
placing an array capacitor with substantially metalized top and bottom exterior surfaces in contact with the micro-vias.

17. The method of claim 16, wherein exposing a plurality of micro-vias in a substrate comprises removing a substantially square region of dielectric material from the substrate.

18. The method of claim 17, further comprising forming a plurality of micro-vias and dielectric layers on top of the array capacitor.

19. The method of claim 18, further comprising attaching an integrated circuit die to the micro-vias.

20. The method of claim 18, wherein removing a substantially square region comprises drilling or etching an area of about 1 square centimeter.
